(19) United States
(12) Patent Application Publication
(10) Pub. No.: US 2025/0299761 A1
(43) Pub. Date: Sep. 25, 2025

(54) SEMICONDUCTOR DEVICE

(71) Applicant: SK hynix Inc., Icheon-si Gyeonggi-do (KR)

(72) Inventors: Jin Hyung LEE, Icheon-si Gyeonggi-do (KR); Su Hyun OH, Icheon-si Gyeonggi-do (KR); Chang Kwon LEE, Icheon-si Gyeonggi-do (KR)

(73) Assignee: SK hynix Inc., Icheon-si Gyeonggi-do (KR)

(21) Appl. No.: 18/792,301

(22) Filed: Aug. 1, 2024

(30) Foreign Application Priority Data
Mar. 22, 2024 (KR) 10-2024-0039447

(51) Int. Cl. G11C 29/32; G11C 29/44; H01L 23/48; H01L 25/065; H01L 25/18

(52) U.S. Cl. CPC G11C 29/32; G11C 29/44; H01L 23/481; H01L 25/0657; H01L 25/18; G11C 2029/4402; H01L 2225/06541

(57) ABSTRACT

A semiconductor device includes a base chip configured to, during a scan operation, connect a first signal path and a second signal path to a first voltage source, a first memory chip configured to, during the scan operation, connect the first signal path to a second voltage source to generate a first fail result signal and output the first fail result signal to the base chip when a chip identification (ID) has a first combination, and a second memory chip configured to, during the scan operation, connect the second signal path to a third voltage source to generate a second fail result signal and to output the second fail result signal to the base chip when the chip ID has a second combination.

### CROSS-REFERENCE TO RELATED APPLICATIONS

The present application claims priority under 35 U.S.C. § 119(a) to Korean Patent Application No. 10-2024-0039447, filed in the Korean Intellectual Property Office on Mar. 22, 2024, which application is incorporated herein by reference in its entirety.

### BACKGROUND

### 1. Technical Field

The present disclosure relates to semiconductor devices that output connection fail information for signal paths connected between a plurality of memory chips and a base chip.

### 2. Related Art

As technology for manufacturing semiconductor devices advances, packaging technologies for a plurality of memory chips in semiconductor devices are also gradually advancing towards higher integration and performance. The packaging technologies for semiconductor devices are developing in a variety of ways, including three-dimensional structures that vertically stack a plurality of memory chips, moving away from the two-dimensional structure in which a plurality of memory chips are arranged in a flat layout on a printed circuit board (PCB). A semiconductor device having a three-dimensional structure can be implemented by stacking a plurality of memory chips using through-silicon vias TSV (hereinafter referred to as a “through electrode”), such as high bandwidth memory (HBM), or by stacking a plurality of memory chips using wire bonding.

### SUMMARY

In accordance with an embodiment of the present disclosure, a semiconductor device may include a base chip configured to drive a first signal path and a second signal path during a scan operation, a first memory chip configured to, during the scan operation, connect the first signal path to a second voltage source to generate a first fail result signal and output the first fail result signal to the base chip when a chip identification (ID) has a first combination, and a second memory chip configured to, during the scan operation, connect the second signal path to a third voltage source to generate a second fail result signal and to output the second fail result signal to the base chip when the chip ID has a second combination.

In accordance with an embodiment of the present disclosure, a semiconductor device may include a base chip configured to generate a fail information signal at a second logic level after generating the fail information signal at a first logic level during a test mode, to drive a signal path to a first voltage level during a scan operation, and to generate the fail information signal based on a fail result signal to detect a connection fail of the signal path, and a memory chip configured to generate the fail result signal at the second logic level after generating the fail result signal at the first logic level during the test mode, to drive the signal path to a second voltage level to generate the fail result signal during the scan operation, and output the fail result signal to the base chip according to a chip identification (ID).

In accordance with an embodiment of the present disclosure, a semiconductor device may include a base chip configured to drive a signal path to a first voltage level during a scan operation and to detect a connection fail of the signal path from a fail information signal generated based on a fail result signal; and a memory chip configured to drive the signal path to a second voltage level during the scan operation to generate the fail result signal and output the fail result signal to the base chip according to a chip identification, wherein the signal path extends through the base chip and the memory chip.

### BRIEF DESCRIPTION OF THE DRAWINGS

FIG. 1 is a block diagram illustrating a configuration of a semiconductor device according to an embodiment of the present disclosure.

FIG. 2 is a block diagram illustrating an embodiment of a base chip included in the semiconductor device according to the present disclosure.

FIG. 3 is a block diagram illustrating an embodiment of a fail information signal generation circuit according to the present disclosure.

FIG. 4 is a diagram illustrating an embodiment of a first fail signal generation circuit according to the present disclosure.

FIG. 5 is a diagram illustrating an embodiment of a second fail signal generation circuit according to the present disclosure.

FIG. 6 is a block diagram illustrating an embodiment of a fail information signal output circuit according to the present disclosure.

FIG. 7 is a block diagram illustrating an embodiment of a first memory chip included in a semiconductor device according to the present disclosure.

FIG. 8 is a diagram illustrating an embodiment of a first fail result signal generation circuit according to the present disclosure.

FIG. 9 is a circuit diagram illustrating to an embodiment of a first memory control circuit included according to the present disclosure.

FIG. 10 is a block diagram illustrating an embodiment of a second memory chip included in a semiconductor device according to the present disclosure.

FIG. 11 is a diagram illustrating an embodiment of a second fail result signal generation circuit according to the present disclosure.

FIG. 12 is a circuit diagram illustrating an embodiment of a second memory control circuit according to the present disclosure.

FIG. 13 is a table results from detecting connection fails in a plurality of signal paths included in a semiconductor device according to an embodiment of the present disclosure.

FIG. 14 is a diagram illustrating an embodiment of a stack memory system according to the present disclosure.

### DETAILED DESCRIPTION

Terms such as “vertical,” “top,” “bottom,” “over,” “on,” “level,” and other terms implying relative spatial relationship or orientation are utilized only for the purpose of ease of description or reference to a drawing and are not otherwise limiting.

Terms such as “first,” “second,” and “third,” are used to distinguish between various elements, and do not imply size, order, priority, quantity, or importance of the elements. Thus, a first element in some examples may be named a second element in other examples without departing from the teachings of the present disclosure.

When an element is referred to as “connected” to another element, the elements may be connected directly or through at least one intervening element between the elements. When an element is referred to as “directly connected” to another element, one element is directly connected to the other element without an intervening element between the two elements.

A logic “high” level and a logic “low” level are used to describe logic levels of electrical signals. A signal at a logic “high” level is distinguished from a signal at a logic “low” level. For example, when a signal at a first voltage corresponds to a signal at a logic “high” level, a signal at a second voltage corresponds to a signal at a logic “low” level. A logic “high” level may be a voltage level that is higher than a voltage level at a logic “low” level. Logic levels of signals may be different or opposite according to the different embodiments. For example, a signal at a logic “high” level in one embodiment may be at a logic “low” level in another embodiment.

Various embodiments of the present disclosure are described in more detail with reference to the accompanying drawings. The embodiments described are for illustrative purposes only and do not limit the scope of the present disclosure.

With high integration and high performance, methods for detecting connection fails in the through electrodes (TSVs) utilized to stack a plurality of memory chips are beneficial. A method for detecting connection fails of the through electrodes, also referred to as TSVs, may be performed through a down-scan operation (through silicon via open short test) including turning on a PMOS transistor connected to the through electrode of the memory chip disposed at a top layer, turning on an NMOS transistor connected to the through electrode of the base chip disposed at a bottom layer, and detecting whether the through electrode is driven to a logic level. A method for detecting connection fails of the through electrodes may be performed using an up-scan operation (through silicon via open short test) including turning on an NMOS transistor connected to the through electrode of the memory chip disposed on a top layer, turning on a PMOS transistor connected to the through electrode of the base chip disposed at a bottom layer, and detecting whether the through electrode is driven at a logic level.

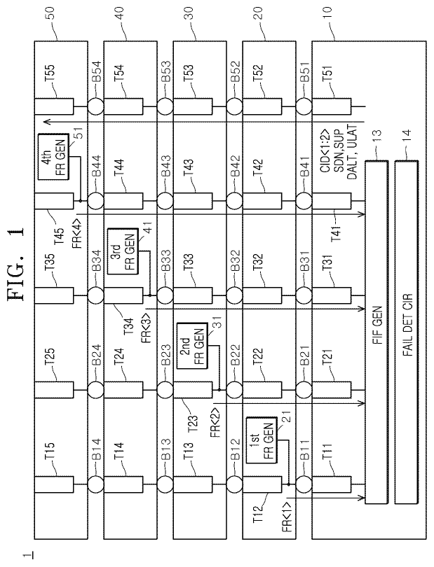

FIG. 1 is a block diagram illustrating a configuration of a semiconductor device 1 according to an embodiment of the present disclosure. As shown in FIG. 1, the semiconductor device 1 includes a base chip 10, a first memory chip 20, a second memory chip 30, a third memory chip 40, and a fourth memory chip 50.

The base chip 10 is electrically connected to first to fifth signal paths. The first signal path electrically connects through electrodes T11, T12, T13, T14, and T15 alternated with bumps B11, B12, B13, and B14. The bumps may be solder balls or other connection structures. The second signal path electrically connects through electrodes T21, T22, T23, T24, and T25 alternated with bumps B21, B22, B23, and B24. The third signal path electrically connects through electrodes T31, T32, T33, T34, and T35 alternated with bumps B31, B32, B33, and B34. The fourth signal path electrically connects through electrodes T41, T42, T43, T44, and T45 alternated with bumps B41, B42, B43, and B44. The fifth signal path electrically connects through electrodes T51, T52, T53, T54, and T55 alternated with bumps B51, B52, B53, and B54. The through electrodes T11 through T15, T21 through T25, T31 through T35, T41 through T45, and T51 through T55 may be made of a conductive material in a cylindrical shape stacked vertically through the base chip 10, the first memory chip 20, the second memory chip 30, the third memory chip 40, and the fourth memory chip 50. The bumps B11 through B14, B21 through B24, B31 through B34, and B41 through B44 may be made of a conductive material in a ball shape directly connected to a printed circuit board. Although five signal paths are shown in the example of FIG. 1, fewer or additional signal paths may be included.

The base chip 10 include the through electrodes T11, T21, T31, T41, and T51, a fail information signal generation circuit 13, and a fail detection circuit 14.

The through electrode T11 is electrically connected to the bump B11. The through electrode T21 is electrically connected to the bump B21. The through electrode T31 is electrically connected to the bump B31. The through electrode T41 is electrically connected the bump B41. The through electrode T51 is electrically connected to the bump B51.

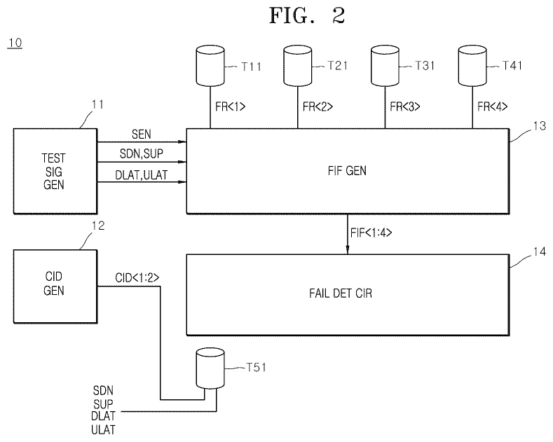

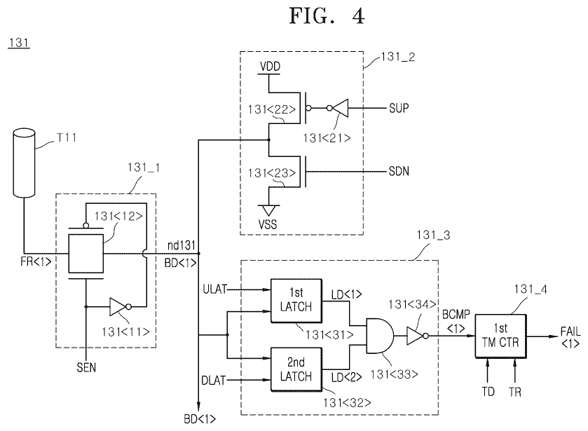

The fail information signal generation circuit FIF GEN 13 connects each of the through electrodes T11, T21, T31, and T41 to a voltage source through one of a PMOS transistor and an NMOS transistor during a scan operation. The fail information signal generation circuit 13 connects the through electrodes T11, T21, T31, and T41 to a power supply voltage, such as VDD in FIG. 4, through the PMOS transistor during the scan operation. The fail information signal generation circuit 13 connects the through electrodes T11, T21, T31, and T41 to a ground voltage, such as VSS in FIG. 4, through the NMOS transistor during the scan operation. The fail information signal generation circuit 13 receives a first fail result signal FR<1> from the first memory chip 20 through the through electrode T11 of the first signal path. The fail information signal generation circuit 13 receives a second fail result signal FR<2> from the second memory chip 30 through the through electrode T21 of the second signal path. The fail information signal generation circuit 13 receives a third fail result signal FR<3> from the third memory chip 40 through the through electrode T31 of the third signal path. The fail information signal generation circuit 13 receives a fourth fail result signal FR<4> from the fourth memory chip 50 through the through electrode T41 of the fourth signal path. The fail information signal generation circuit 13 serializes the first fail result signal through the fourth fail result signal FR<1:4> to generate the first fail information signal through the fourth fail information signal, such as FIF<1:4> in FIG. 2.

The fail detection circuit 14 detect connections fails of the first signal path through the fourth signal path based on the fail information signals FIF<1:4> during the scan operation. The fail detection circuit 14 detects any connection fail of the through electrodes T11, T12, T13, T14, and T15 and the bumps B11, B12, B13, and B14 of the first signal path based on the first fail information signal FIF<1> during the scan operation. The fail detection circuit 14 detects any connection fail of the through electrodes T21, T22, T23, T24, and T25 and the bumps B21, B22, B23, and B24 of the second signal path based on the second fail information signal FIF<2> during the scan operation. The fail detection circuit 14 detects any connection fail of the through electrodes T31, T32, T33, T34, and T35 and the bumps B31, B32, B33, and B34 of the third signal path based on the third fail information signal FIF<3 during the scan operation. The fail detection circuit 14 detects any connection fail of the through electrodes T41, T42, T43, T44, and T45 and the bumps B41, B42, B43, and B44 of the fourth signal path based on the fourth fail information signal FIF<4> during the scan operation.

The base chip 10 connects each of the first signal path to a voltage source through the fourth signal path through one of a PMOS transistor and an NMOS transistor during the scan operation. The base chip 10 receive the fail result signals FR<1:4> during the scan operation. The base chip 10 serializes the fail result signals FR<1:4> to generate the fail information signals FIF<1:4> during the scan operation. The base chip 10 detects the connection fails of the first signal path through the fourth signal path based on the fail information signals FIF<1:4>. The base chip 10 outputs a first chip identification (ID) CID<1> and a second chip ID CID<2>, collectively chip IDs CID<1:2>, a scan-down signal SDN, a scan-up signal SUP, a down-latch signal DLAT, and an up-latch signal ULAT through the through electrode T51. The through electrode T51 is shown as a single through electrode, but may be implemented as a plurality of through electrodes that output the first chip ID CID<1>, the second chip ID CID<2>, the scan-down signal SDN, the scan-up signal SUP, the down-latch signal DLAT, and the up-latch signal ULAT, which signals may be output separately.

The first memory chip 20 is electrically connected to the bumps B11, B21, B31, B41, and B51 stacked over or disposed on the base chip 10.

The first memory chip 20 includes the through electrodes T12, T22, T32, T42, and T52 and a first fail result signal generation circuit 21.

The through electrode T12 is electrically connected to the bump B11 and the bump B12. The through electrode T22 is electrically connected to the bump B21 and the bump B22. The through electrode T32 is electrically connected to the bump B31 and the bump B32. The through electrode T42 is electrically connected to the bump B41 and the bump B42. The through electrode T52 is electrically connected to the bump B51 and the bump B52.

The first fail result signal generation circuit 21 is electrically connected to the through electrode T12 of the first signal path. The first fail result signal generation circuit 21 connects the first signal path to a voltage source through one of a PMOS transistor and an NMOS transistor based on the scan-down signal SDN and the scan-up signal SUP when the chip IDs CID<1:2> have a first combination. The first fail result signal generation circuit 21 generates the first fail result signal FR<1> for the first signal path. The first fail result signal generation circuit 21 outputs the first fail result signal FR<1> to the first signal path.

The second memory chip 30 is electrically connected to the bumps B12, B22, B32, B42, and B52 stacked over or disposed on the first memory chip 20.

The second memory chip 30 includes the through electrodes T13, T23, T33, T43, and T53 and a second fail result signal generation circuit 31.

The through electrode T13 is electrically connected to the bump B12 and the bump B13. The through electrode T23 is electrically connected to the bump B22 and the bump B23. The through electrode T33 is electrically connected to the bump B32 and the bump B33. The through electrode T43 is electrically connected to the bump B42 and the bump B43. The through electrode T53 is electrically connected to the bump B52 and the bump B53.

The second fail result signal generation circuit 31 is electrically connected to the through electrode T23 of the second signal path. The second fail result signal generation circuit 31 connects the second signal path to a voltage source through one of a PMOS transistor and an NMOS transistor based on the scan-down signal SDN and the scan-up signal SUP when the chip IDs CID<1:2> have a second combination. The second fail result signal generation circuit 31 generates the second fail result signal FR<2> for the second signal path. The second fail result signal generation circuit 31 outputs the second fail result signal FR<2> to the second signal path.

The third memory chip 40 is electrically connected to the bumps B13, B23, B33, B43, and B53 stacked over or disposed on the second memory chip 30.

The third memory chip 40 includes the through electrodes T14, T24, T34, T44, and T54 and a third fail result signal generation circuit 41.

The through electrode T14 is electrically connected to the bump B13 and the bump B14. The through electrode T24 is electrically connected to the bump B23 and the bump B24. The through electrode T34 is electrically connected to the bump B33 and the bump B34. The through electrode T44 is electrically connected to the bump B43 and the bump B44. The through electrode T54 is electrically connected to the bump B53 and the bump B54.

The third fail result signal generation circuit 41 is electrically connected to the through electrode T34 of the third signal path. The third fail result signal generation circuit 41 connects the third signal path to a voltage source through one of a PMOS transistor and an NMOS transistor based on the scan-down signal SDN and the scan-up signal SUP when the chip IDs CID<1:2> have a third combination. The third fail result signal generation circuit 41 generates the third fail result signal FR<3> for the third signal path. The third fail result signal generation circuit 41 outputs the third fail result signal FR<3> to the third signal path.

The fourth memory chip 50 is electrically connected to the bumps B14, B24, B34, B44, and B54 stacked over or disposed on the third memory chip 40.

The fourth memory chip 50 includes the through electrodes T15, T25, T35, T45, and T55 and a fourth fail result signal generation circuit 51.

The through electrode T15 is electrically connected to the bump B14. The through electrode T25 is electrically connected to the bump B24. The through electrode T35 is electrically connected to the bump B34. The through electrode T45 is electrically connected to the bump B44. The through electrode T55 is electrically connected to the bump B54.

The fourth fail result signal generation circuit 51 is electrically connected to the through electrode T45 of the fourth signal path. The fourth fail result signal generation circuit 51 connects the fourth signal path to a voltage source through one of a PMOS transistor and an NMOS transistor based on the scan-down signal SDN and the scan-up signal SUP when the chip IDs CID<1:2> have a fourth combination. The fourth fail result signal generation circuit 51 generates the fourth fail result signal FR<4> for the fourth signal path. The fourth fail result signal generation circuit 51 outputs the fourth fail result signal FR<4> to the fourth signal path.

Although the four memory chips 20, 30, 40, and 50 are stacked over the base chip 10 in FIG. 1, other quantities of memory chips, such as eight or sixteen memory chips, may be stacked.

The semiconductor device 1 shown in FIG. 1 is implemented by stacking the base chip 10 and the memory chips 20, 30, 40, and 50 utilizing the through silicon vias TSVs similar to a high bandwidth memory (HBM) system. Alternatively, a plurality of memory chips may be stacked and connected utilizing bonding wires. Depending on the embodiment, the bonding wires may be signal paths for the signals input to and output from the base chip 10 and the memory chips 20, 30, 40, and 50.

FIG. 2 is a block diagram illustrating an embodiment of the base chip 10, for example, as included in the semiconductor device 1 shown in FIG. 1. The base chip 10 includes a test signal generation circuit 11, a chip ID generation circuit 12, the fail information signal generation circuit 13, and the fail detection circuit 14.

The test signal generation circuit 11 generates a scan enable signal SEN that is enabled during the scan operation. The test signal generation circuit 11 generates the scan-down signal SDN and the scan-up signal SUP that are selectively enabled during the scan operation. The test signal generation circuit 11 generates the down-latch signal DLAT and the up-latch signal ULAT that are selectively enabled during the scan operation. The test signal generation circuit 11 outputs the scan enable signal SEN, the scan-down signal SDN, the scan-up signal SUP, the down-latch signal DLAT, and the up-latch signal ULAT to the memory chips 20, 30, 40, and 50 through the through electrode T51 of the fifth signal path. The test signal generation circuit 11 may be implemented by logic gates or a processor and memory including instructions that, when executed by the processor, generate the scan enable signal SEN, the scan-down signal SDN, the scan-up signal SUP, the down-latch signal DLAT, and the up-latch signal ULAT during the scan operation according to TIMING AND OTHER DETAILS NEED TO BE DESCRIBED HERE.

The chip ID generation circuit 12 sequentially generates chip IDs CID<1:2>, for example, by counting, such as <0:0>, <0:1>, <1:0>, <1:1>. The chip ID generation circuit 12 may be implemented with a two-bit counter or a longer counter to address more than two bits. The chip ID generation circuit 12 generates the chip IDs CID<1:2> having the first combination. The chip ID generation circuit 12 generates the chip IDs CID<1:2> having the second combination after generating the chip IDs CID<1:2> having the first combination. The chip ID generation circuit 12 generates the chip IDs CID<1:2> having the third combination after generating the chip IDs CID<1:2> having the second combination. The chip ID generation circuit 12 generates the chip IDs CID<1:2> having the fourth combination after generating the chip IDs CID<1:2> having the third combination. For example, the first combination includes when the first chip ID CID<1> is generated at a logic “low” level and the second chip ID CID<2> is generated at a logic “low” level. The second combination includes when the first chip ID CID<1> is generated at a logic “high” level and the second chip ID CID<2> is generated at a logic “low” level. The third combination includes when the first chip ID CID<1> is generated at a logic “low” level and the second chip ID CID<2> is generated at a logic “high” level. The fourth setting combination includes when the first chip ID CID<1> is generated at a logic “high” level and the second chip ID CID<2> is generated at a logic “high” level. The chip ID generation circuit 12 is implemented to generate the chip IDs CID<1:2> that are sequentially counted, but may be implemented to generate the chip IDs CID<1:2> having one combination of logic level for the first setting combination, the second combination, the third combination, and the fourth combination depending on the embodiment. The chip ID generation circuit 12 outputs the first and second chip IDs CID<1:2> through the through electrode T51 of the fifth signal path to the memory chips 20, 30, 40, and 50.

The fail information signal generation circuit 13 is electrically connected to the through electrodes T11, T21, T31, and T41. During the test mode, the fail information signal generation circuit 13 generates the fail information signals FIF<1:4> at a second logic level (logic “high” level) after generating the fail information signals FIF<1:4> at a first logic level (logic “low” level). During the scan operation, the fail information signal generation circuit 13 connects the through electrodes T11, T21, T31, and T41 to a voltage source through one of the PMOS transistor and the NMOS transistor. During the scan operation, the fail information signal generation circuit 13 connects the through electrodes T11, T21, T31, and T41 to a voltage source through one of the PMOS transistor and the NMOS transistor based on the scan-down signal SDN and the scan-up signal SUP. During the scan operation, the fail information signal generation circuit 13 connects the through electrodes T11, T21, T31, and T41 to the power supply voltage, such as VDD in FIG. 4, through the PMOS transistor when the scan enable signal SEN and the scan-up signal SUP are enabled. During the scan operation, the fail information signal generation circuit 13 connects the through electrodes T11, T21, T31, and T41 to the ground voltage, such as VSS in FIG. 4, through the NMOS transistor when the scan enable signal SEN and the scan-down signal SDN are enabled. During the scan operation, the fail information signal generation circuit 13 latches the logic levels of the through electrodes T11, T21, T31, and T41 based on the down-latch signal DLAT and the up-latch signal ULAT. During the scan operation, the fail information signal generation circuit 13 generates the fail information signals FIF<1:4> based on the latched logic levels at the through electrodes T11, T21, T31, and T41. During the scan operation, the fail information signal generation circuit 13 receives the first fail result signal FR<1> from the first memory chip 20 through the through electrode T11 of the first signal path. During the scan operation, the fail information signal generation circuit 13 receives the second fail result signal FR<2> from the second memory chip 30 through the through electrode T21 of the second signal path. During the scan operation, the fail information signal generation circuit 13 receives the third fail result signal FR<3> from the third memory chip 40 through the through electrode T31 of the third signal path. During the scan operation, the fail information signal generation circuit 13 receives the fourth fail result signal FR<4> from the fourth memory chip 50 through the through electrode T41 of the fourth signal path. The fail information signal generation circuit 13 serializes the fail result signals FR<1:4> to generate the fail information signals FIF<1:4>.

During the scan operation, the fail detection circuit 14 detects the connection fails of the first signal path through the fourth signal path based on the fail information signals FIF<1:4>. During the scan operation, the fail detection circuit 14 detects or identifies an open fail in which at least one of the first signal path through the fourth signal path includes an open circuit or a disconnect by detecting or identifying the logic levels of the fail information signals FIF<1:4>. During the scan operation, the fail detection circuit 14 detects the logic levels of the fail information signals FIF<1:4> to identify a short fail in which at least two paths of the first signal path through the fourth signal path are connected to each other. During the scan operation, the fail detection circuit 14 detects the logic levels of the fail information signals FIF<1:4> to detect a resistance defect in which at least two paths of the first signal path through the fourth signal paths are connected to each other through a small or limited resistance. The fail detection circuit 14 may be implemented by logic gates or a processor and memory including instructions that, when executed by the processor, generate the scan enable signal SEN, the scan-down signal SDN, the scan-up signal SUP, the down-latch signal DLAT, and the up-latch signal ULAT during the scan operation according to TIMING AND OTHER DETAILS NEED TO BE DESCRIBED HERE.

During the test mode, the base chip 10 generates the fail information signals FIF<1:4> at the second logic level (logic “high” level) after generating the fail information signals FIF<1:4> at the first logic level (logic “low” level). During the scan operation, the base chip 10 connects each of the first signal path through the fourth signal path to a voltage source through one of the PMOS transistor and the NMOS transistor. During the scan operation, the base chip 10 receive the fail result signals FR<1:4> through the respective signal paths. During the scan operation, the base chip 10 serializes the fail result signals FR<1:4> to generate the fail information signals FIF<1:4>. The base chip 10 detects the connection fails in the first signal path through the fourth signal path based on the fail information signals FIF<1:4>.

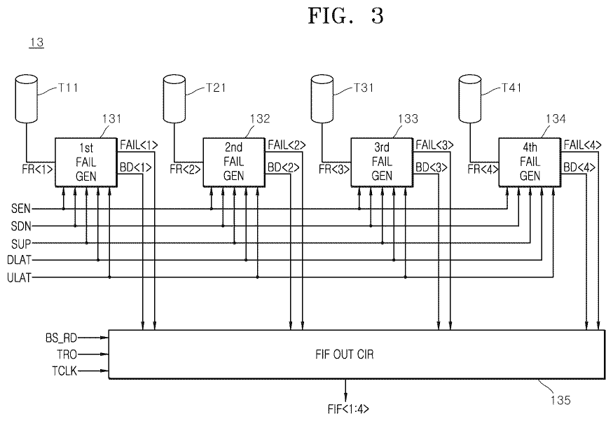

FIG. 3 is a block diagram illustrating an embodiment of the fail information signal generation circuit 13, for example, as included in the base chip 10 shown in FIG. 2. The fail information signal generation circuit 13 includes a first fail signal generation circuit 131, a second fail signal generation circuit 132, a third fail signal generation circuit 133, a fourth fail signal generation circuit 134, and a fail detection signal output circuit 135.

The first fail signal generation circuit 131 is electrically connected to the through electrode T11 of the first signal path. During the test mode, the first fail signal generation circuit 131 generate a first fail signal FAIL<1> at the second logic level (logic “high” level) after generating the first fail signal FAIL<1> at the first logic level (logic “low” level). The first fail signal generation circuit 131 receives the first fail result signal FR<1> through the first through electrode T11 when the scan enable signal SEN is enabled. The first fail signal generation circuit 131 generates first base data BD<1> based on the first fail result signal FR<1> when the scan enabled signal SEN is enabled. The first fail signal generation circuit 131 generates the first fail signal FAIL<1> for the through electrode T11 based on the scan enable signal SEN, the scan-down signal SDN, the scan-up signal SUP, the down-latch signal DLAT, and the up-latch signal ULAT. The first fail signal generation circuit 131 connects the through electrode T11 to a voltage source through an NMOS transistor, such as 131<23> in FIG. 4, when the scan enable signal SEN is enabled and the scan-down signal SDN is enabled. The first fail signal generation circuit 131 latches the logic level of the through electrode T11 driven by the NMOS transistor (131<23> in FIG. 4) when the down-latch signal DLAT is enabled. The first fail signal generation circuit 131 connects the through electrode T11 to a voltage source through a PMOS transistor (131<22> in FIG. 4) when the scan enable signal SEN is enabled and the scan-up signal SUP is enabled. The first fail signal generation circuit 131 latches the logic level of the through electrode T11 driven by the PMOS transistor (131<22> in FIG. 4) when the up-latch ULAT is enabled. The first fail signal generation circuit 131 generates the first fail signal FAIL<1> based on the logic level of the through electrode T11 driven by the NMOS transistor 131<23> in FIG. 4 and the logic level of the through electrode T11 driven by the PMOS transistor 131<22> in FIG. 4.

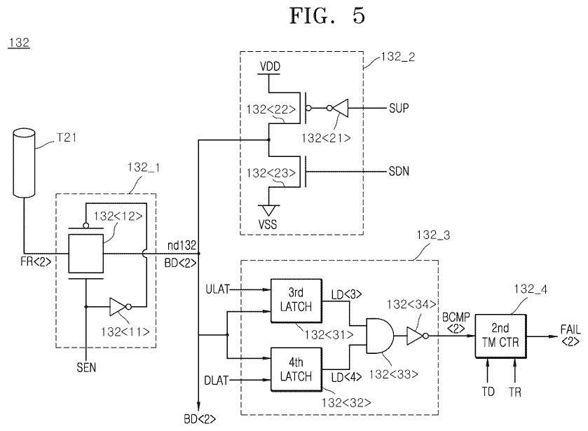

The second fail signal generation circuit 132 is electrically connected to the through electrode T21 of the second signal path. During the test mode, the second fail signal generation circuit 132 generates a second fail signal FAIL<2> at the second logic level (logic “high” level) after generating the second fail signal FAIL<2> at the first logic level (logic “low” level). The second fail signal generation circuit 132 receives the second fail result signal FR<2> through the through electrode T21 when the scan enable signal SEN is enabled. The second fail signal generation circuit 132 generates second base data BD<2> based on the second fail result signal FR<2> when the scan enable signal SEN is enabled. The second fail signal generation circuit 132 generates the second fail signal FAIL<2> for the through electrode T21 based on the scan enable signal SEN, the scan-down signal SDN, the scan-up signal SUP, the down-latch signal DLAT, and the up-latch signal ULAT. The second fail signal generation circuit 132 connects the through electrode T21 to a voltage source through an NMOS transistor 132<23> in FIG. 5 when the scan enable signal SEN is enabled and the scan-down signal SDN is enabled. The second fail signal generation circuit 132 latches the logic level of the through electrode T21 driven by the NMOS transistor 132<23> in FIG. 5 when the down-latch signal DLAT is enabled. The second fail signal generation circuit 132 connects the through electrode T21 to a voltage source through a PMOS transistor 132<22> in FIG. 5 when the scan enable signal SEN is enabled and the scan-up signal SUP is enabled. The second fail signal generation circuit 132 latches the logic level of the through electrode T21 driven by the PMOS transistor 132<22> in FIG. 5 when the up-latch signal ULAT is enabled. The second fail signal generation circuit 132 generates the second fail signal FAIL<2>based on the logic level of the through electrode T21 driven by the NMOS transistor 132<23> in FIG. 5 and the logic level of the through electrode T21 driven by the PMOS transistor 132<22> in FIG. 5.

The third fail signal generation circuit 133 is electrically connected to the through electrode T31 of the third signal path. During the test mode, the third fail signal generation circuit 133 generates a third fail signal FAIL<3> at the second logic level (logic “high” level) after generating the third fail signal FAIL<3> at the first logic level (logic “low” level). The third fail signal generation circuit 133 receives the third fail result signal FR<3>through the through electrode T31 when the scan enable signal SEN is enabled. The third fail signal generation circuit 133 generates third base data BD<3> based on the third fail result signal FR<3> when the scan enable signal SEN is enabled. The third fail signal generation circuit 133 generates the third fail signal FAIL<3> for the through electrode T31 based on the scan enable signal SEN, the scan-down signal SDN, the scan-up signal SUP, the down-latch signal DLAT, and the up-latch signal ULAT. The third fail signal generation circuit 133 connects the through electrode T31 to a voltage source through an NMOS transistor (not shown) when the scan enable signal SEN is enabled and the scan-down signal SDN is enabled. The third fail signal generation circuit 133 latches the logic level of the through electrode T31 driven by the NMOS transistor (not shown) when the down-latch signal DLAT is enabled. The third fail signal generation circuit 133 connects the through electrode T31 to a voltage source through a PMOS transistor (not shown) when the scan enable signal SEN is enabled and the scan-up signal SUP is enabled. The third fail signal generation circuit 133 latches the logic level of the through electrode T31 driven by the PMOS transistor (not shown) when the up-latch signal ULAT is enabled. The third fail signal generation circuit 133 generates the third fail signal FAIL<3> based on the logic level of the through electrode T31 driven by the NMOS transistor (not shown) and the logic level of the through electrode T31 driven by the PMOS transistor (not shown).

The fourth fail signal generation circuit 134 is electrically connected to the through electrode T41 of the fourth signal path. During the test mode, the fourth fail signal generation circuit 134 generates a fourth fail signal FAIL<4> at the second logic level (logic “high” level) after generating the fourth fail signal FAIL<4> at the first logic level (logic “low” level). The fourth fail signal generation circuit 134 receives the fourth fail result signal FR<4> through the through electrode T41 when the scan enable signal SEN is enabled. The fourth fail signal generation circuit 134 generates fourth base data BD<4> based on the fourth fail result signal FR<4> when the scan enable signal SEN is enabled. The fourth fail signal generation circuit 134 generates the fourth fail signal FAIL<4> for the through electrode T41 based on the scan enable signal SEN, the scan-down signal SDN, the scan-up signal SUP, the down-latch signal DLAT, and the up-latch signal ULAT. The fourth fail signal generation circuit 134 connects the through electrode T41 to a voltage source through an NMOS transistor (not shown) when the scan enable signal SEN is enabled and the scan-down signal SDN is enabled. The fourth fail signal generation circuit 134 latches the logic level of the through electrode T41 driven by the NMOS transistor (not shown) when the down-latch signal DLAT is enabled. The fourth fail signal generation circuit 134 connects the through electrode T41 to a voltage source through a PMOS transistor (not shown) when the scan enable signal SEN is enabled and the scan-up signal SUP is enabled. The fourth fail signal generation circuit 134 latches the logic level of the through electrode T41 driven by the PMOS transistor (not shown) when the up-latch signal ULAT is enabled. The fourth fail signal generation circuit 134 generates the fourth fail signal FAIL<4> based on the logic level of the through electrode T41 driven by the NMOS transistor (not shown) and the logic level of the through electrode T41 driven by the PMOS transistor (not shown).

The fail information signal output circuit 135 serializes the base data BD<1:4> based on a test read signal TRO in synchronization with a test clock signal TCLK to output the serialized base data BD<1:4> as the fail information signals FIF<1:4>. The fail information signal output circuit 135 serializes the base data BD<1:4> in synchronization with the test clock signal TCLK when the test read signal TRO is enabled to output the serialized base data BD<1:4> as the fail information signals FIF<1:4>. The fail information signal output circuit 135 serializes the fail signals FAIL<1:4> based on a base read signal BS_RD in synchronization with the test clock signal TCLK to output the serialized fail signals FAIL<1:4> as the fail information signals FIF<1:4>. The fail information signal output circuit 135 serializes the fail signals FAIL<1:4> in synchronization with the test clock signal TCLK when base read signal BS_RD is enabled to output the serialized fail signals FAIL<1:4> as the fail information signals FIF<1:4>.

FIG. 4 is a diagram illustrating an embodiment of the first fail signal generation circuit 131, for example, as included in the fail information signal generation circuit 13 shown in FIG. 3. The first fail signal generation circuit 131 includes a first switching circuit 131_1, a first driving circuit 131_2, a first storage circuit 131_3, and a first test mode control circuit 131_4.

The first switching circuit 131_1 includes an inverter 131<11> and a transmission gate 131<12> or switch. The first switching circuit 1311 connects the through electrode T11 to a node nd131 when the scan enable signal SEN is enabled at a logic “high” level. The first switching circuit 1311 generates the first base data BD<1> from the first fail result signal FR<1> input through the through electrode T11 when the scan enable signal SEN is enabled at a logic “high” level. The first switching circuit 131_1 blocks connection between the through electrode T11 and the node nd131 when the scan enable signal SEN is disabled at a logic “low” level.

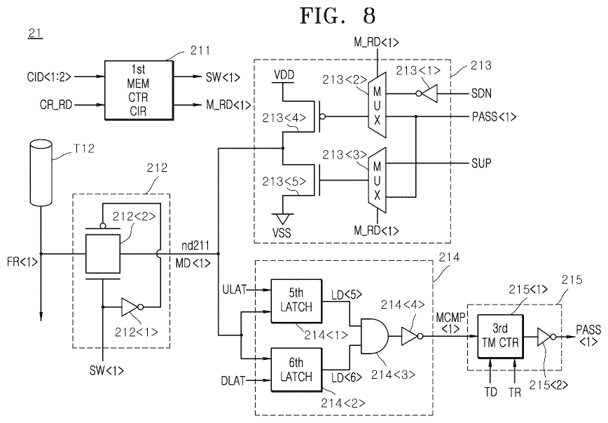

The first driving circuit 131_2 includes an inverter 131<21>, a PMOS transistor 131<22>, and an NMOS transistor 131<23>. The inverter 131<21> inverts the scan-up signal SUP to output an inverted scan-up signal to the PMOS transistor 131<22>. The PMOS transistor 131<22> is connected between the power supply voltage VDD and the node nd131 and drives the node nd131 to the voltage level of the power supply voltage VDD to generate the first base data BD1 at a logic “high” level when an output signal of the inverter 131<21> is at a logic “low” level. The NMOS transistor 131<23> is connected between the node nd131 and a ground voltage VSS and drives the node nd131 to a voltage level of the ground voltage VSS to generate the first base data BD1 at a logic “low” level when the scan-down signal SDN is at a logic “high” level. The PMOS transistor 131<22> of the first driving circuit 131_2 may have a driving force greater than the driving force of the NMOS transistor 213<5> in FIG. 8 of the first fail result signal generation circuit 21. When no fail is detected in the through electrodes T11, T12, T13, and T14 of the first signal path, the first driving circuit 131_2 connects the through electrodes T11, T12, T13, and T14 to the voltage level of the power supply voltage VDD.

The first storage circuit 131_3 includes a first latch 131<31>, a second latch 131<32>, an AND gate 131<33>, and an inverter 131<34>. The first latch 131<31> latches the first base data BD<1> when the up-latch signal ULAT is enabled at a logic “high” level. The first latch 131<31> outputs the latched first base data BD<1> as first latch data LD<1>. The second latch 131<32> latches the first base data bd<1> when the down-latch signal DLAT is enabled at a logic “high” level. The second latch 131<32> outputs the latched first base data BD<1> as second latch data LD<2>. The AND gate 131<33> and the inverter 131<34> generate a first base comparison signal BCMP<1> according to the logic levels of the first latch data LD<1> and the second latch data LD<2>. The AND gate 131<33> and the inverter 131<34> generate the first base comparison signal BCMP<1> at a logic “low” level when the first latch data LD<1> is at a logic “high” level and the second latch data LD<2> is at a logic “high” level. The AND gate 131<33> and the inverter 131<34> generate the first base comparison signal BCMP<1> at a logic “high” level when at least one of the first latch data LD<1> and the second latch data LD<2> is at a logic “low” level.

The first test mode control circuit 131_4 generates the first fail signal FAIL<1> from the first base comparison signal BCMP<1> based on a test disable signal TD and a test reset signal TR. The first test mode control circuit 131_4 generates the first fail signal FAIL<1> at the first logic level (logic “low” level) when the test disable signal TD is enabled at a logic “high” level. The first test mode control circuit 131_4 generates the first fail signal FAIL<1> at the second logic level (logic “high” level) when the test reset signal TR is enabled at a logic “high” level. The first test mode control circuit 131_4 outputs the first base comparison signal BCMP<1> as the first fail signal FAIL<1> when the test disable signal TD is disabled at a logic “low” level and the test reset signal TR is disabled at a logic “low” level. The test disable signal TD is a signal that is enabled at a logic “high” level when no fail is detected in the plurality of signal paths during the test mode. The test reset signal TR is a signal that is enabled at a logic “high” level when a fail is detected in the plurality of signal paths during the test mode. The test disable signal TD and the test reset signal TR are signals that are sequentially enabled during the test mode. The test disable signal TD and the test reset signal TR may be signals that are applied from an external test device during the test mode.

FIG. 5 is a diagram illustrating an embodiment of the second fail signal generation circuit 132, for example, as included in the fail information signal generation circuit 13 shown in FIG. 3. The second fail signal generation circuit 132 includes a second switching circuit 132_1, a second driving circuit 132_2, a second storage circuit 132_3, and a second test mode control circuit 132_4.

The second switching circuit 132_1 includes an inverter 132<11> and a transmission gate 132<12> or switch. The first switching circuit 132_1 connects the through electrode T21 to a node nd132 when the scan enable signal SEN is enabled at a logic “high” level. The second switching circuit 132_1 generates the second base data BD<2> from the second fail result signal FR<2> input through the through electrode T21 when the scan enable signal SEN is enabled at a logic “high” level. The second switching circuit 132_1 blocks connection between the through electrode T21 and the node nd132 when the scan enable signal SEN is disabled at a logic “low” level.

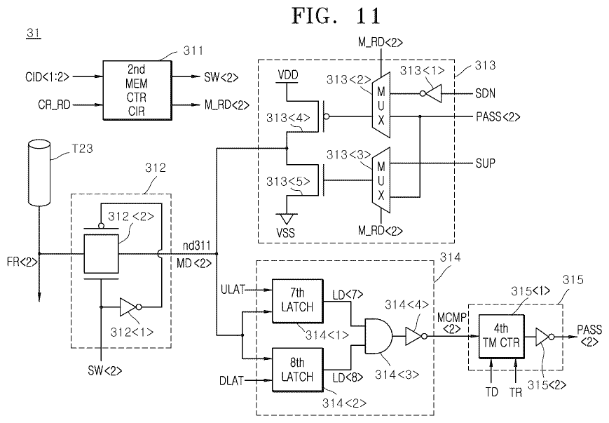

The second driving circuit 132_2 includes an inverter 132<21>, a PMOS transistor 132<22>, and an NMOS transistor 132<23>. The inverter 132<21> inverts the scan-up signal SUP to output an inverted scan-up signal to the PMOS transistor 132<22>. The PMOS transistor 132<22> is connected between the power supply voltage VDD and the node nd132 and drives the node nd132 at the voltage level of the power supply voltage VDD to generate the second base data BD2 at a logic “high” level when an output signal of the inverter 132<21> is at a logic “low” level. The NMOS transistor 132<23> is connected between the node nd132 and the ground voltage VSS and drives the node nd132 to the voltage level of the ground voltage VSS to generate the second base data BD2 at a logic “low” level when the scan-down signal SDN is at a logic “high” level. The PMOS transistor 132<22> of the second driving circuit 132_2 may have a driving force greater than the driving force of the NMOS transistor 313<5> in FIG. 11 of the second fail result signal generation circuit 22. When no fail is detected in the through electrodes T21, T22, T23, and T24 of the second signal path, the second driving circuit 132_2 connects the through electrodes T21, T22, T23, and T24 to the voltage level of the power supply voltage VDD.

The second storage circuit 132_3 includes a third latch 132<31>, a fourth latch 132<32>, an AND gate 132<33>, and an inverter 132<34>. The third latch 132<31> latches the second base data BD<2> when the up-latch signal ULAT is enabled at a logic “high” level. The third latch 132<31> outputs the latched second base data BD<2> as third latch data LD<3>. The fourth latch 132<32> latches the second base data BD<2> when the down-latch signal DLAT is enabled at a logic “high” level. The fourth latch 132<32> outputs the latched second base data BD<2> as fourth latch data LD<4>. The AND gate 132<33> and the inverter 132<34> generate a second base comparison signal BCMP<2> according to the logic levels of the third latch data LD<3> and the fourth latch data LD<4>. The AND gate 132<33> and the inverter 132<34> generate the second base comparison signal BCMP<2> at a logic “low” level when the third latch data LD<3> is at a logic “high” level and the fourth latch data LD<4> is at a logic “high” level. The AND gate 132<33> and the inverter 132<34> generate the second base comparison signal BCMP<2> at a logic “high” level when at least one of the third latch data LD<3> and the fourth latch data LD<4> is at a logic “low” level.

The second test mode control circuit 132_4 generates the second fail signal FAIL<2> from the second base comparison signal BCMP<2> based on the test disable signal TD and the test reset signal TR. The second test mode control circuit 132_4 generates the second fail signal FAIL<2> at the first logic level (logic “low” level) when the test disable signal TD is enabled at a logic “high” level. The second test mode control circuit 132_4 generate the second fail signal FAIL<2> at the second logic level (logic “high” level) when the test reset signal TR is enabled at a logic “high” level. The second test mode control circuit 132_4 outputs the second base comparison signal BCMP<2> as the second fail signal FAIL<2> when the test disable signal TD is disabled at a logic “low” level and the test reset signal TR is disabled at a logic “low” level.

The third fail signal generation circuit 133 shown in FIG. 3 is electrically connected to the through electrode T31 to generate third base data BD<3> and the third fail signal FAIL<3> and is implemented with the same circuit and performs the same functions as the first fail signal generation circuit 131 or the second fail signal generation circuit 132 shown in FIG. 4 or FIG. 5. The fourth fail signal generation circuit 134 shown in FIG. 3 is electrically connected to the through electrode T41 to generate fourth base data BD<4> and the fourth fail signal FAIL<4>, and is implemented with the same circuit and performs the same functions as the first fail signal generation circuit 131 or the second fail signal generation circuit 132 shown in FIG. 4 or FIG. 5.

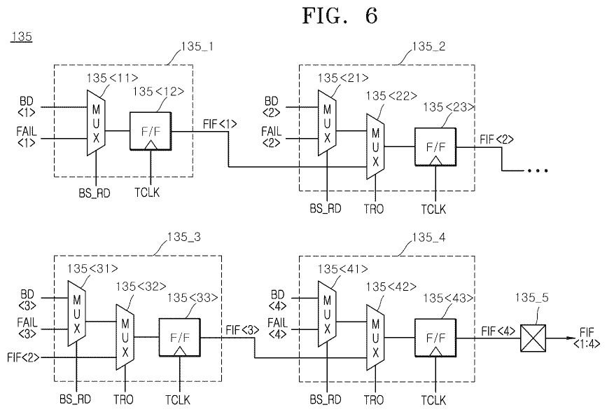

FIG. 6 is a diagram illustrating an embodiment of the fail information signal output circuit 135, for example, as included in the fail information signal generation circuit 13 shown in FIG. 3. The fail information signal output circuit 135 includes a first fail information signal output circuit 135_1, a second fail information signal output circuit 135_2, a third fail information signal output circuit 135_3, and a fourth fail information signal output circuit 135_4. The flip-flops of FIG. 6 may be D flip-flops.

The first fail information signal output circuit 135_1 includes a multiplexer 135<11> and a flip-flop 135<12>. The multiplexer 135<11> receives the first base data BD<1> to output the first base data BD<1> when a base read signal BS_RD is disabled at a logic “low” level. The multiplexer 135<11> receives the first fail signal FAIL<1> to output the first fail signal FAIL<1> when the base read signal BS_RD is enabled at a logic “high” level. The flip-flop 135<12> outputs an output signal of the multiplexer 135<11> as the first fail information signal FIF<1> when the logic level of the test clock signal TCLK transitions from a logic “low” level to a logic “high” level. The first fail information signal output circuit 135_1 outputs the first base data BD<1> as the first fail information signal FIF<1> in synchronization with the test clock signal TCLK when the base read signal BS_RD is disabled. The first fail information signal output circuit 135_1 outputs the first fail signal FAIL<1> as the first fail information signal FIF<1> in synchronization with the test clock signal TCLK when the base read signal BS_RD is enabled.

The second fail information signal output circuit 135_2 includes multiplexers 135<21> and 135<22> and a flip-flop 135<23>. The multiplexer 135<21> receives the second base data BD<2> to output the second base data BD<2> when the base read signal BS_RD is disabled at a logic “low” level. The multiplexer 135<21> receives the second fail signal FAIL<2> to output the second fail signal FAIL<2> when the base read signal BS_RD is enabled at a logic “high” level. The multiplexer 135<22> receives an output signal of the multiplexer 135<21> to output the output signal of the multiplexer 135<21> when the test read signal TRO is disabled at a logic “low” level. The multiplexer 135<22> receives the first fail information signal FIF<1> to output the first fail information signal FIF<1> when the test read signal TRO is enabled at a logic “high” level. The flip-flop 135<23> outputs an output signal of the multiplexer 135<22> as the second fail information signal FIF<2> when the logic level of the test clock signal TCLK transitions from a logic “low” level to a logic “high” level. The second fail information signal output circuit 135_2 outputs the second base data BD<2> as the second fail information signal FIF<2> in synchronization with the test clock signal TCLK when the base read signal BS_RD is disabled and the test read signal TRO is disabled. The second fail information signal output circuit 135_2 outputs the second fail signal FAIL<2> as the second fail information signal FIF<2> in synchronization with the test clock signal TCLK when the base read signal BS_RD is enabled and the test read signal TRO is disabled. The second fail information signal output circuit 135_2 outputs the first fail information signal FIF<1> as the second fail information signal FIF<2> in synchronization with the test clock signal TCLK when the test read signal TRO is enabled.

The third fail information signal output circuit 135_3 includes multiplexers 135<31> and 135<32> and a flip-flop 135<33>. The multiplexer 135<31> receives the third base data BD<3> to output the third base data BD<3> when the base read signal BS_RD is disabled at a logic “low” level. The multiplexer 135<31> receives the third fail signal FAIL<3> to output the third fail signal FAIL<3> when the base read signal BS_RD is enabled at a logic “high” level. The multiplexer 135<32> receives an output signal of the multiplexer 135<31> to output the output signal of the multiplexer 135<31> when the test read signal TRO is disabled at a logic “low” level. The multiplexer 135<32> receives the second fail information signal FIF<2> to output the second fail information signal FIF<2> when the test read signal TRO is enabled at a logic “high” level. The flip-flop 135<33> outputs an output signal of the multiplexer 135<32> as the third fail information signal FIF<3> when the logic level of the test clock signal TCLK transitions from a logic “low” level to a logic “high” level. The third fail information signal output circuit 135_3 outputs the third base data BD<3> as the third fail information signal FIF<3> in synchronization with the test clock signal TCLK when the base read signal BS_RD is disabled and the test read signal TRO is disabled. The third fail information signal output circuit 135_3 outputs the third fail signal FAIL<3> as the third fail information signal FIF<3> in synchronization with the test clock signal TCLK when the base read signal BS_RD is enabled and the test read signal TRO is disabled. The third fail information signal output circuit 135_3 outputs the second fail information signal FIF<2> as the third fail information signal FIF<3> in synchronization with the test clock signal TCLK when the test read signal TRO is enabled.

The fourth fail information signal output circuit 135_4 includes multiplexers 135<41> and 135<42> and a flip-flop 135<43>. The multiplexer 135<41> receives the fourth base data BD<4> to output the fourth base data BD<4> when the base read signal BS_RD is disabled at a logic “low” level. The multiplexer 135<41> receives the fourth fail signal FAIL<4> to output the fourth fail signal FAIL<4> when the base read signal BS_RD is enabled at a logic “high” level. The multiplexer 135<42> receives an output signal of the multiplexer 135<41> to output the output signal of the multiplexer 135<41> when the test read signal TRO is disabled at a logic “low” level. The multiplexer 135<42> receives the third fail information signal FIF<3> to output the third fail information signal FIF<3> when the test read signal TRO is enabled at a logic “high” level. The flip-flop 134<43> generates the fourth fail information signal FIF<4> based on an output signal of the multiplexer 135<42> to output the fourth fail information signal FIF<4> to the output pad 135<5> when the logic level of the test clock signal TCLK transitions from a logic “low” level to a logic “high” level. The fourth fail information signal output circuit 135_4 generates the fourth fail information signal FIF<4> based on the fourth base data BD<4> in synchronization with the test clock signal TCLK to output the fourth fail information signal FIF<4> to the output pad 135<5> when the base read signal BS_RD is disabled and the test read signal TRO is disabled. The fourth fail information signal output circuit 135_4 generates the fourth fail information signal FIF<4> based on the fourth fail signal FAIL<4> in synchronization with the test clock signal TCLK to output the fourth fail information signal FIF<4> to the output pad 135<5> when the base read signal BS_RD is enabled and the test read signal TRO is disabled. The fourth fail information signal output circuit 135_4 generates the fail information signal FIF<4>, based on the third fail information signal FIF<3> in synchronization with the test clock signal TCLK to output the fourth fail information signal FIF<4> to the output pad 135<5> when the teat read signal TRO is enabled.

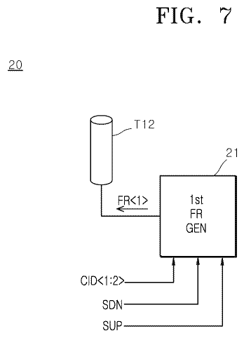

FIG. 7 is a block diagram illustrating an embodiment of the first memory chip 20, for example, as included in the semiconductor device 1 shown in FIG. 1. The first memory chip 20 includes a first fail result signal generation circuit 21.

The first fail result signal generation circuit 21 receives the chip IDs CID<1:2>, the scan-down signal SDN, and the scan-up signal SUP from the base chip 10. The chip IDs CID<1:2>, the scan-down signal SDN, and the scan-up signal SUP are input from the base chip 10 to the first fail result signal generation circuit 21 through the through electrode T51.

The first fail result signal generation circuit 21 is electrically connected to the through electrode T12 of the first signal path. The first fail result signal generation circuit 21 generates the first fail result signal FR<1> at the second logic level (logic “high” level) after generating the first fail result signal FR<1> at the first logic level (logic “low” level) in the test mode. The first fail result signal generation circuit 21 connects the through electrode T12 to a voltage source through one of a PMOS transistor and an NMOS transistor during the scan operation. The first fail result signal generation circuit 21 connects the through electrode T12 to a voltage source through one of the PMOS transistor and the NMOS transistor based on the scan-down signal SDN and the scan-up signal SUP when the chip IDs CID<1:2> have a first combination during the scan operation. The first fail result signal generation circuit 21 generates the first fail result signal FR<1> according to the logic level of the through electrode T12 driven by one of the PMOS transistor and the NMOS transistor during the scan operation. The first fail result signal generation circuit 21 outputs the first fail result signal FR<1> to the through electrode T12 of the first signal path.

FIG. 8 is a diagram illustrating an embodiment of the first fail result signal generation circuit 21, for example, as included in the first memory chip 20 as shown in FIG. 1 or FIG. 7. The first fail result signal generation circuit 21 includes a first memory control circuit 211, a third switching circuit 212, a third driving circuit 213, a third storage circuit 214, and a first core test mode control circuit 215.

The first memory control circuit 211 generates a first switching signal SW<1> and a first memory read signal M_RD<1>, based on a core read signal CR_RD and the chip IDs CID<1:2>. The first memory control circuit 211 generate the first switching signal SW<1> and the first memory read signal M_RD<1> when the core read signal CR_RD is enabled and the chip IDs CID<1:2> have the first combination. The core read signal CD_RD is a signal that is enabled at a logic “high” level to perform a core read operation CORE READ that outputs the fail result signals FR<1:4> from the memory chips 20, 30, 40, and 50 to the base chip 10.

The third switching circuit 212 includes an inverter 212<1> and a transmission gate 212<2> or switch. The third switching circuit 212 connects the through electrode T12 to a node nd211 when the first switching signal SW<1> is enabled at a logic “high” level. The third switching circuit 212 blocks connection between the through electrode T12 and the node nd211 when the first switching signal SW<1> is disabled at a logic “low” level.

The third driving circuit 213 includes an inverter 213<1>, multiplexers 213<2> and 213<3>, a PMOS transistor 213<4>, and an NMOS transistor 213<5>. The inverter 213<1> inverts the scan-down signal SDN to output the inverted scan-down signal. The multiplexer 213<2> receives an output signal of the inverter 213<1> to output the output signal of the inverter 213<1> when the first memory read signal M_RD<1> is disabled at a logic “low” level. The multiplexer 213<2> receives a first pass signal PASS<1> to output the first pass signal PASS<1> when the first memory read signal M_RD<1> is enabled at a logic “high” level. The multiplexer 213<3> receives the scan-up signal SUP to output the scan-up signal SUP when the first memory read signal M_RD<1> is disabled at a logic “low” level. The multiplexer 213<3> receives the first pass signal PASS<1> to output the first pass signal PASS<1> when the first memory read signal M_RD<1> is enabled at a logic “high” level. The PMOS transistor 213<4> is connected between the power supply voltage VDD and the node nd211 and drives the node nd211 to the voltage level of the power supply voltage VDD to generate first memory data MD<1> at a logic “high” level when the output signal of the multiplexer 213<2> is at a logic “low” level. The NMOS transistor 213<5> is connected between the node nd211 and the ground voltage VSS and drives the node nd211 to the voltage level of the ground voltage VSS to generate the first memory data MD<1> at a logic “low” level when an output signal of the multiplexer 213<3> is at a logic “high” level. The PMOS transistor 213<4> of the third driving circuit 213 may have a driving force greater than the driving force of the NMOS transistor 131<23> in FIG. 4 of the first fail signal generation circuit 131. When no fail is detected in the through electrodes T11, T12, T13, T14, and T15 and the bumps B11, B12, 2B13, and B14 of the first signal path, the third driving circuit 213 drives the through electrodes T11, T12, T13, T14, and T15 and the bumps B11, B12, 2B13, and B14 to the voltage level of the power supply voltage VDD.

The third storage circuit 214 includes a fifth latch 214<1>, a sixth latch 214<2>, an AND gate 214<3>, and an inverter 214<4>. The fifth latch 214<1> latches the first memory data MD<1> when the up-latch signal ULAT is enabled at a logic “high” level. The fifth latch 214<1> outputs the latched first memory data MD<1> as fifth latch data LD<5>. The sixth latch 214<2> latches the first memory data MD<1> when the down-latch signal DLAT is enabled at a logic “high” level. The sixth latch 214<2> outputs the latched first memory data MD<1> as sixth latch data LD<6>. The AND gate 214<3> and the inverter 214<4> generate a first memory comparison signal MCMP<1> according to the logic levels of the fifth latch data LD<5> and the sixth latch data LD<6>. The AND gate 214<3> and the inverter 214<4> generate the first memory comparison signal MCMP<1> at a logic “low” level when the fifth latch data LD<5> is at a logic “high” level and the sixth latch data LD<6> is at a logic “high” level. The AND gate 214<3> and the inverter 214<4> generate the first memory comparison signal MCMP<1> at a logic “high” level when at least one of the fifth latch data LD<5> and the sixth latch data LD<6> is at a logic “low” level.

The first core test mode control circuit 215 includes a third test mode control circuit 215<1> and an inverter 215<2>.

The third test mode control circuit 215<1> generates the first pass signal PASS<1> from the first memory comparison signal MCMP<1> based on the test disable signal TD and the test reset signal TR. The third test mode control circuit 215<1> generate an output signal at the first logic level (logic “low” level) when the test disable signal TD is enabled at a logic “high” level. The third test mode control circuit 215<1> generates the output signal at the second logic level (logic “high” level) when the test reset signal TR is enabled at a logic “high” level. The third test mode control circuit 215<1> outputs the first memory comparison signal MCMP<1> as the output signal when the test disable signal TD is disabled at a logic “low” level and the test reset signal TR is disabled at a logic “low” level.

The inverter 215<2> inverts the output signal of the third test mode control circuit 215<1> to generate the first pass signal PASS<1>. The inverter 215<2> generates the first pass signal PASS<1> at the second logic level (logic “high” level) when the output signal of the third test mode control circuit 215<1> is at the first logic level (logic “low” level). The inverter 215<2> generates the first pass signal PASS<1> at the first logic level (logic “low” level) when the output signal of the third test mode control circuit 215<1> is at the second logic level (logic “high” level).

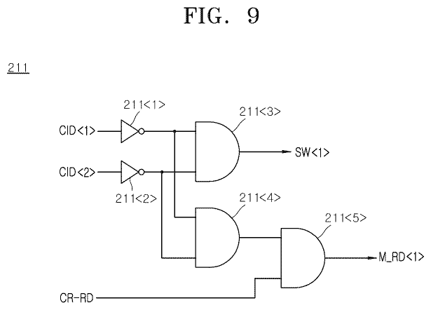

FIG. 9 is a circuit diagram illustrating an embodiment of the first memory control circuit 211, for example, as included in the first fail result signal generation circuit 21 shown in FIG. 8.

The first memory control circuit 211 is implemented with inverters 211<1> and 211<2> and AND gates 211<3>, 211<4>, and 211<5>.

The inverter 211<1> inverts the first chip ID CID<1> to output the inverted first chip ID. The inverter 211<2> inverts the second chip ID CID<2> to output the inverted second chip ID. The AND gate 211<3> generates the first switching signal SW<1> that is enabled at a logic “high” level when an output signal of the inverter 211<1> is at a logic “high” level and an output signal of the inverter 211<2> is at a logic “high” level. The AND gate 211<4> generates an output signal at a logic “high” level when the output signal of the inverter 211<1> is at a logic “high” level and the output signal of the inverter 211<2> is at a logic “high” level. The AND gate 211<5> generates the first memory read signal M_RD<1> that is enabled at a logic “high” level when the core read signal CR_RD is at a logic “high” level and the output signal of the AND gate 211<4> is at a logic “high” level.

The first memory control circuit 211 generates the first switching signal SW<1> that is enabled at a logic “high” level when the first chip ID CID<1> is at a logic “low” level and the second chip ID CID<2> is at a logic “low” level. The first memory control circuit 211 generates the first memory read signal M_RD<1> that is enabled at a logic “high” level when the core read signal CR_RD is enabled at a logic “high” level, the first chip ID CID<1> is at a logic “low” level, and the second chip ID CID<2> is at a logic “low” level. The first memory control circuit 211 generates the first switching signal SW<1> and the first memory read signal M_RD<1> that are enabled at logic “high” levels when the core read signal CR_RD is enabled at a logic “high” level and the first and second chip IDs CID<1:2> have the first combination. The core read signal is a signal that is enabled at a logic “high” level to output, to the base chip 10 after the scan operation, the fail result signals FR<1:4> generated in the memory chips 20, 30, 40, and 50.

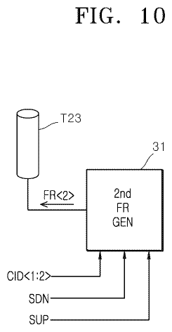

FIG. 10 is a block diagram illustrating an embodiment of the second memory chip 30, for example, as included in the semiconductor device 1 shown in FIG. 1. The second memory chip 30 includes a second fail result signal generation circuit 31.

The second fail result signal generation circuit 31 receives the IDs CID<1:2>, the scan-down signal SDN, and the scan-up signal SUP from the base chip 10 in FIG. 1. The chip IDs CID<1:2>, the scan-down signal SDN, and the scan-up signal SUP are input from the base chip 10 to the second fail result signal generation circuit 31 through the through electrode T51 and the through electrode T52.

The second fail result signal generation circuit 31 is electrically connected to the through electrode T23 of the second signal path. The second fail result signal generation circuit 31 generates the second fail result signal FR<2> at the second logic level (logic “high” level) after generating the second fail result signal FR<2> at the first logic level (logic “low” level) during the test mode. During the scan operation, the second fail result signal generation circuit 3 connects the through electrodes T21, T22, T23, and T24 to a voltage source through one of a PMOS transistor and an NMOS transistor. During the scan operation, the second fail result signal generation circuit 31 connects the through electrode T23 to a voltage source, based on the scan-down signal SDN and the scan-up signal SUP, through one of the PMOS transistor and the NMOS transistor when the chip IDs CID<1:2> have the second combination. During the scan operation, the second fail result signal generation circuit 31 generates the second fail result signal FR<2> according to the logic level of the through electrode T23 driven by one of the PMOS transistor and the NMOS transistor. The second fail result signal generation circuit 31 outputs the second fail result signal FR<2> to the through electrode T23 of the second signal path.

FIG. 11 is a block diagram illustrating an embodiment of the second fail result signal generation circuit 31, for example, as included in the second memory chip 30 shown in FIG. 1 or FIG. 10. The second fail result signal generation circuit 31 includes a second memory control circuit 311, a fourth switching circuit 312, a fourth driving circuit 313, a fourth storage circuit 314, and a second core test mode control circuit 315.

The second memory control circuit 311 generates the second switching signal SW<2> and the second memory read signal M_RD<2> based on the core read signal CR_RD and the IDs CID<1:2>. The second memory control circuit 311 generates the second switching signal SW<2> and the second memory read signal M_RD<2> that are enabled at logic “high” levels when the core read signal CR_RD is enabled and the chip IDs CID<1:2> have the second combination.

The fourth switching circuit 312 includes an inverter 312<1> and a transmission gate 312<2> or switch. The fourth switching circuit 312 connects the through electrode T23 to a node nd311 when the second switching signal SW<2> is enabled at a logic “high” level. The fourth switching circuit 312 blocks connection between the through via T23 and the node nd311 when the second switching signal SW<2> is disabled at a logic “low” level.

The fourth driving circuit 313 includes an inverter 313<1>, multiplexers 313<2> and 313<3>, a PMOS transistor 313<4>, and an NMOS transistor 313<5>. The inverter 313<1> inverts the scan-down signal SDN to output the inverted scan-down signal SDN. The multiplexer 313<2> receives an output signal of the inverter 313<1> to output the output signal of the inverter 313<1> when the second memory read signal M_RD<2> is disabled at a logic “low” level. The multiplexer 313<2> receives the second pass signal PASS<2> to output the second pass signal PASS<2> when the second memory read signal M_RD<2> is enabled at a logic “high” level. The multiplexer 313<3> receives the scan-up signal SUP to output the scan-up signal SUP when the second memory read signal M_RD<2> is disabled at a logic “low” level. The multiplexer 313<3> receives the second pass signal PASS<2> to output the second pass signal PASS<2> when the second memory read signal M_RD<2> is enabled at a logic “high” level. The PMOS transistor 331<4> is connected between the power supply voltage VDD and the node nd311 and drives the node nd311 to the voltage level of the power supply voltage VDD to generate the second memory data MD<2> at a logic “high” level when an output signal of the multiplexer 313<2> is at a logic “low” level. The NMOS transistor 313<5> is connected between the node nd311 and the ground voltage VSS and drives the node nd311 to the voltage level of the ground voltage VSS to generate the second memory data MD<2> at a logic “low” level when an output signal of the multiplexer 313<3> is at a logic “high” level. The PMOS transistor 313<4> of the fourth driving circuit 313 may have a driving force greater than the driving force of the NMOS transistor 132<23> in FIG. 5 of the second fail signal generation circuit 132. When no fail in the through electrodes T21, T22, T23, and T24 of the second signal path is detected, the fourth driving circuit 313 drives the through electrodes T21, T22, T23, and T24 to the voltage level of the power supply voltage VDD.

The fourth storage circuit 314 includes a seventh latch 314<1>, an eighth latch 314<2>, an AND gate 314<3>, and an inverter 314<4>. The seventh latch 314<1> latches the second memory data MD<2> when the up-latch signal ULAT is enabled at a logic “high” level. The seventh latch 314<1> outputs the latched second memory data MD<2> as seventh latch data LD<7>. The eighth latch 314<2> latches the second memory data MD<2> when the down-latch signal DLAT is enabled at a logic “high” level. The eighth latch 314<2> outputs the latched second memory data MD<2> as eighth latch data LD<8>. The AND gate 314<3> and the inverter 314<4> generate a second memory comparison signal MCMP<2> according to the logic levels of the seventh latch data LD<7> and the eighth latch data LD<8>. The AND gate 314<3> and the inverter 314<4> generate the second memory comparison signal MCMP<2> at a logic “low” level when the seventh latch data LD<7> is at a logic “high” level and the eighth latch data LD<8> is at a logic “high” level. The AND gate 314<3> and the inverter 314<4> generate the second memory comparison signal MCMP<2> at a logic “high” level when at least one of the seventh latch data LD<7> and the eighth latch data LD<8> is at a logic “low” level.

The second core test mode control circuit 315 includes a fourth test mode control circuit 315<1> and an inverter 315<2>.

The fourth test mode control circuit 315<1> generates an output signal from the second memory comparison signal MCMP<2> based on the test disable signal TD and the test reset signal TR. The fourth test mode control circuit 315<1> generates the output signal at the first logic level (logic “low” level) when the test disable signal TD is enabled at a logic “high” level. The fourth test mode control circuit 315<1> generates the output signal at the second logic level (logic “high” level) when the test reset signal TR is enabled at a logic “high” level. The fourth test mode control circuit 315<1> outputs the second memory comparison signal MCMP<2> as the output signal when the test disable signal TD is disabled at a logic “low” level and the test reset signal TR is disabled at a logic “low” level.

The inverter 315<2> inverts the output signal of the fourth test mode control circuit 315<1> to generate the second pass signal PASS<2>. The inverter 315<2> generates the second pass signal PASS<2> at the second logic level (logic “high” level) when the output signal of the fourth test mode control circuit 315<1> is at the first logic level (logic “low” level). The inverter 315<2> generates the second pass signal PASS<2> at the first logic level (logic “low” level) when the output signal of the fourth test mode control circuit 315<1> is at the second logic level (logic “high” level).

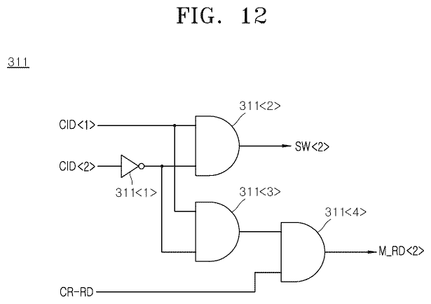

FIG. 12 is a circuit diagram illustrating an embodiment of the second memory control circuit 311, for example, as included in the second fail result signal generation circuit 31 shown in FIG. 11.

The second memory control circuit 311 is implemented with an inverter 311<1> and AND gates 311<2>, 311<3>, and 311<4>.

The inverter 311<1> inverts the second chip ID CID<2> to output the inverted second chip ID. The AND gate 311<2> generate the second switching signal SW<2> that is enabled at a logic “high” level when the first chip ID CID<1> is at a logic “high” level and an output signal of the inverter 311<1> is at a logic “high” level. The AND gate 311<3> generates an output signal at a logic “high” level when the first chip ID CID<1> is at a logic “high” level and the output signal of the inverter 311<1> is at a logic “high” level. The AND gate 311<3> generates the second memory read signal M_RD<2> that is enabled at a logic “high” level when the core read signal CR_RD is at a logic “high” level and the output signal of the AND gate 311<3> is at a logic “high” level.

The second memory control circuit 311 generates the second switching signal SW<2> that is enabled at a logic “high” level when the first chip ID CID<1> is at a logic “high” level and the second chip ID CID<2> is at a logic “low” level. The second memory control circuit 311 generates the second memory read signal M_RD<2> that is enabled at a logic “high” level when the core read signal CR_RD is at a logic “high” level, the first chip ID CID<1> is at a logic “high” level, and the second chip ID CID<2> is at a logic “low” level. The second memory control circuit 311 generates the second switching signal SW<2> and the second memory read signal M_RD<2> that are enabled at a logic “high” level when the core read signal CR_RD is enabled at a logic “high” and the first and second chip IDs CID<1:2> have the second combination.

The third fail result signal generation circuit 41 included in the third memory chip 40 shown in FIG. 1 is electrically connected to the through electrode T34 of the third signal path and is implemented with the same circuit and performs the same functions as the first fail result signal generation circuit 21 such as shown FIG. 8 or the second fail result signal generation circuit 31 such as shown in FIG. 11. The fourth fail result signal generation circuit 51 included in the fourth memory chip 50 shown in FIG. 1 is electrically connected to the through electrode T45 of the fourth signal path and is implemented with the same circuit and performs the same functions as the first fail result signal generation circuit 21 such as shown FIG. 8 or the second fail result signal generation circuit 31 such as shown in FIG. 11.

As described above, the semiconductor device 1 according to an embodiment of the present disclosure outputs the connection fail information of a plurality of signal paths connecting the plurality of memory chips 20, 30, 40, and 50 to the base chip 10. The semiconductor device 1 provides a plurality of fail result signals generated by detecting any connection fails of the signal paths within the plurality of memory chips and the base chip 10.

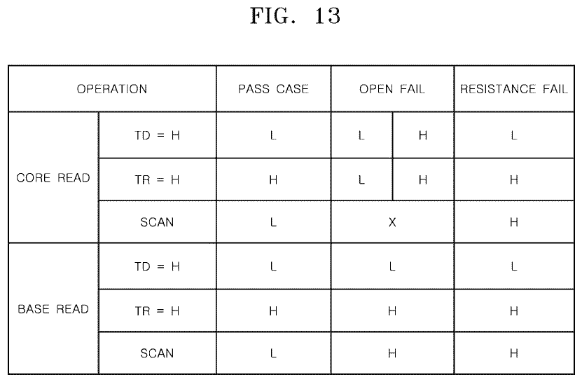

FIG. 13 is a table including results from detecting connection fails in the first signal path through the fourth signal path included in the semiconductor device 1 according to an embodiment of the present disclosure.

Referring to FIG. 13, an example of a pass result PASS when no connection fail is detected in the four signal paths during a core read operation CORE READ is described.

During the core read operation CORE READ, the fail result signal generation circuits 21, 31, 41, and 51 included in the memory chips 20, 30, 40, and 50, respectively, generate the fail result signals FR<1:4> at the first logic level (logic “low” level) when the test disable signal TD is enabled at a logic “high” level during the test mode.

During the core read operation CORE READ, the fail information signal generation circuit 13 included in the base chip 10 serializes the fail result signals FR<1:4> to generate the fail information signal FIF<1:4> at the first logic level (logic “low” level).

During the core read operation CORE READ, the fail information signal generation circuits 21, 31, 41, and 51 included in the first to fourth memory chips 20, 30, 40, and 50 generate the fail result signals FR<1:4> at the second logic level (logic “high” level) when the test reset signal TR is enabled at a logic “high” level during the test mode.

During the core read operation CORE READ, the fail information signal generation circuit 13 included in the base chip 10 serializes the fail result signals FR<1:4> to generate the fail information signal FIF<1:4> at the second logic level (logic “high” level).

During the scan operation, the memory chips 20, 30, 40, and 50 connect the first signal path through the fourth signal path to a voltage source or voltage level to generate the fail result signals FR<1:4>. When no connection fail in the four signal paths is detected, referred to as a pass result PASS, the fail result signals FR<1:4> are generated at the first logic level (logic “low” level).

During the core read operation CORE READ, the fail information signal generation circuit 13 included in the base chip 10 serializes the fail result signals FR<1:4> to generate the fail information signal FIF<1:4> at the first logic level (logic “low” level). The fail detection circuit 14 detects the fail information signal FIF<1:4> at the first logic level (logic “low” level) to detect or identify that no fail is detected in the first signal path through the fourth signal path.

Referring to FIG. 13, an example of a pass result PASS when no connection fail is detected in the four signal paths during the base read operation BASE READ is described.

During the base read operation BASE READ, the fail information signal generation circuit 13 included in the base chip 10 generates the fail information signal FIF<1:4> at the first logic level (logic “low” level) when the test disable signal TD is enabled at a logic “high” level during the test mode.

During the base read operation BASE READ, the fail information signal generation circuit 13 included in the base chip 10 generates the fail information signal FIF<1:4> at the second logic level (logic “high” level) when the test reset signal TR is enabled at a logic “high” level during the test mode.

During the scan operation SCAN, the base chip 10 connects the first signal path through the fourth signal path to a voltage source or voltage level to generate the first to fourth fail signals FAIL<1:4>. When no fail is detected in the first signal path through the fourth signal path, the fail signals FAIL<1:4> are generated at the first logic level (logic “low” level).

During the base read operation BASE READ, the fail information signal generation circuit 13 included in the base chip 10 serializes the fail signals FAIL<1:4> to generate the fail information signals FIF<1:4> at the first logic level (logic “low” level). The fail detection circuit 14 detects the fail information signal FIF<1:4> at the first logic level (logic “low” level) to detect or identify when no fail is detected in the first signal path through the fourth signal path.

Referring to FIG. 13, an example when an open fail OPEN FAIL is detected in one or more of the four signal paths during the core read operation CORE READ is described.

During the core read operation CORE READ, the fail result signal generation circuits 21, 31, 41, and 51 included in the first to fourth memory chips 20, 30, 40, and 50, respectively, generate the fail result signals FR<1:4> at the first logic level (logic “low” level) or the second logic level (logic “high” level) in response to detecting an open fail when the test disable signal TD is enabled during the test mode.

During the core read operation CORE READ, the fail information signal generation circuit 13 included in the base chip 10 serializes the fail result signals FR<1:4> to generate the fail information signals FIF<1:4> at the first logic level (logic “low” level) or the second logic level (logic “high” level).

During the core read operation CORE READ, the fail result signal generation circuits 21, 31, 41, and 51 included in the memory chips 20, 30, 40, and 50, respectively, generate the fail result signals FR<1:4> at the first logic level (logic “low” level) or the second logic level (logic “high” level) in response to detection of an open fail when the test reset signal TR is enabled at a logic “high” level during the test mode.

During the core read operation CORE READ, the fail information signal generation circuit 13 included in the base chip 10 serializes the fail result signals FR<1:4> to generate the fail information signals FIF<1:4> at the first logic level (logic “low” level) or the second logic level (logic “high” level).

The fail detection circuit 14 detects an open fail in at least one of the first signal path through the fourth signal path when the fail information signals FIF<1:4> are generated at one of the first logic level (logic “low” level) at the second logic level (logic “high” level) when the test disable signal TD is enabled and the test reset signal TR is enabled and the fail information signals FIF<1:4> generated during the scan operation SCAN are at the same logic level.

Referring to FIG. 13, an example when an open fail OPEN FAIL is detected in the four signal paths during the base read operation BASE READ is described.

During the base read operation BASE READ, the fail information signal generation circuit 13 included in the base chip 10 generates the fail information signals FIF<1:4> at the first logic level (logic “low” level) when the test disable signal TD is enabled at a logic “high” level during the test mode.

During the base read operation BASE READ, the fail information signal generation circuit 13 included in the base chip 10 generate the fail information signals FIF<1:4> at the second logic level (logic “high” level) when the test reset signal TR is enabled at a logic “high” level during the test mode.

During the scan operation SCAN, the base chip 10 connects the first signal path through the fourth signal path to a voltage source to generate the fail signals FAIL<1:4>. When an open fail OPEN FAIL is detected in at least one of the first signal path through the fourth signal path, the fail signals FAIL<1:4> are generated at the second logic level (logic “high” level).

During the base read operation BASE READ, the fail information signal generation circuit 13 included in the base chip 10 serializes the fail signals FAIL<1:4> to generate the fail information signals FIF<1:4> at the first logic level (logic “low” level). The fail detection circuit 14 detects the fail information signals FIF<1:4> at the second logic level (logic “high” level) to detect an open fail in at least one of the first signal path through the fourth signal path.

Referring to FIG. 13, an example when a resistance fail RESISTANCE FAIL is detected in the four signal paths during the core read operation CORE READ is described.

During the core read operation CORE READ, the fail result signal generation circuits 21, 31, 41, and 51 included in the memory chips 20, 30, 40, and 50, respectively, generate the fail result signals FR<1:4> at the first logic level (logic “low” level) when the test disable signal TD is enabled at a logic “high” level during the test mode.

During the core read operation CORE READ, the fail information signal generation circuit 13 included in the base chip 10 serializes the fail result signals FR<1:4> to generate the fail information signals FIF<1:4> at the first logic level (logic “low” level).

During the core read operation CORE READ, the fail result signal generation circuits 21, 31, 41, and 51 included in the memory chips 20, 30, 40, and 50, respectively, generate the fail result signals FR<1:4> at the second logic level (logic “high” level) when the test reset signal TR is enabled at a logic “high” level during the test mode.

During the core read operation CORE READ, the fail information signal generation circuit 13 included in the base chip 10 serializes the fail result signals FR<1:4> to generate the fail information signals FIF<1:4> at the second logic level (logic “high” level).

During the scan operation, the memory chips 20, 30, 40, and 50 connect the first signal path through the fourth signal path to generate the fail result signals FR<1:4>. When a resistance fail is detected in at least one of the first signal path through the fourth signal path, the fail result signals FR<1:4> are generated at the second logic level (logic “high” level).

During the core read operation CORE READ, the fail information signal generation circuit 13 included in the base chip 10 serializes the fail result signals FR<1:4> to generate the fail information signal FIF<1:4> at the second logic level (logic “high” level). The fail detection circuit 14 detects the fail information signal FIF<1:4> at the second level (logic “high” level) to detect a resistance fail in any of the first signal path through the fourth signal path.

Referring to FIG. 13, an example when a resistance fail RESISTANCE FAIL is detected in the four signal paths during the base read operation BASE READ is described.

During the base read operation BASE READ, the fail information signal generation circuit 13 included in the base chip 10 generates the fail information signals FIF<1:4> at the first logic level (logic “low” level) when the test disable signal TD is enabled at a logic “high” level during the test mode.

During the base read operation BASE READ, the fail information signal generation circuit 13 included in the base chip 10 generates the fail information signals FIF<1:4> at the second logic level (logic “high” level) when the test reset signal TR is enabled at a logic “high” level during the test mode.

During the scan operation SCAN, the base chip 10 connects the first signal path through the fourth signal path to a voltage source to generate the fail signals FAIL<1:4>. When a resistance fail RESISTANCE FAIL is detected in any of the first signal path through the fourth signal path, the fail signals FAIL<1:4> are generated at the second logic level (logic “high” level).

During the base read operation BASE READ, the fail information signal generation circuit 13 included in the base chip 10 serializes the fail signals FAIL<1:4> to generate the fail information signals FIF<1:4> of the second logic level (logic “high” level). The fail detection circuit 14 detects or identify a resistance fail RESISTANCE FAIL in at least one of the first signal path through the fourth signal path when the fail information signals FIF<1:4> are at the second logic level (logic “high” level).

As described above, the semiconductor device 1 according to an embodiment of the disclosure outputs, to the base chip 10, the connection fail information of the plurality of signal paths connected to the plurality of memory chips 20, 30, 40, and 50. The semiconductor chip 1 detects the connection fails of the plurality of signal paths by detecting or interpreting the plurality of fail result signals generated by detecting the connection fails of the signal paths within the plurality of memory chips.

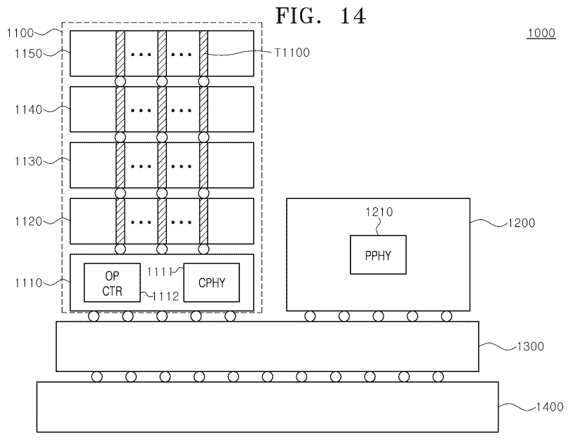

FIG. 14 is a diagram illustrating an embodiment of a stack memory system 1000 according to the present disclosure. As shown in FIG. 14, the stack memory system 1000 includes a semiconductor device 1100, a processor 1200, an interposer 1300, and a substrate 1400.

The interposer 1300 is disposed over the substrate 1400, and the semiconductor device 1100 and the processor 1200 are disposed over the interposer 1300. The interposer 1300 electrically connects the substrate 1400, the semiconductor device 1100, and the processor 1200 to each other. The pitch differences between the substrate 1400, the semiconductor device 1100, and the processor 1200 are large such that the substrate 1400, the semiconductor device 1100, and the processor 1200 are electrically connected using the interposer 1300 including variously formed wires or other forms of connectors.

The processor 1200 includes a processor interface circuit (PPHY) 1210. The processor 1200 applies signals including chip IDs, commands, and addresses that control various internal operations of the semiconductor device 1100 through the processor interface circuit 1210 to the semiconductor device 1100 and receives data from the semiconductor device 1100 through the processor interface circuit 1210.

The semiconductor device 1100 includes a base chip 1110 and a plurality of memory chips 1120, 1130, 1140 and 1150. The semiconductor device 1100 may be implemented with the similar circuitry and to perform similar functions as the semiconductor device 1 shown in FIG. 1.

Each of the memory chips 1120, 1130, 1140 and 1150 is sequentially stacked over the base chip 1110 and a receives various signals from the base chip 1110 through a plurality of through vias T1100.

The base chip 1110 includes a core interface circuit (CPHY) 1111 and an operation control circuit (OP CTR) 1112. The core interface circuit 1111 communicates with the processor interface circuit 1210 to transmit signals including chip IDs, commands, addresses, and so forth transmitted from the processor 1200 to the operation control circuit 1112 and to provide data generated in the operation control circuit 1112 to the processor 1200. The core interface circuit 1111 may be implemented with similar circuitry and to perform the same functions as the test signal generation circuit 11 and the chip ID generation circuit 12 shown in FIG. 2. The operation control circuit 1112 may be implemented with similar circuitry and to perform the same functions as the fail information signal generation circuit 13 and the fail detection circuit 14 shown in FIG. 2.

The semiconductor device 1100 outputs the connection fail information of the plurality of signal paths connected to the plurality of memory chips 1120, 1130, 1140, and 1150 to the base chip 1110. The semiconductor device 1100 detects a plurality of fail result signals generated from detecting any connection fails of the signal paths inside the plurality of memory chips 1120, 1130, 1140, and 1150.

Concepts have been disclosed in conjunction with embodiments as described above. Those skilled in the art will understand that various modifications, additions, and substitutions are possible, without departing from the scope and spirit of the present disclosure. Accordingly, the embodiments disclosed in the present specification should be considered not from a restrictive standpoint but rather from an illustrative standpoint. Therefore, the scope of the present disclosure should not be limited to the foregoing embodiments. All changes within the meaning and range of equivalency of the claims are included within their scope.

What is claimed is:

1. A semiconductor device comprising:
a base chip configured to, during a scan operation, connect a first signal path and a second signal path to a first voltage source;
a first memory chip configured to, during the scan operation, connect the first signal path to a second voltage source to generate a first fail result signal and output the first fail result signal to the base chip when a chip identification (ID) has a first combination; and
a second memory chip configured to, during the scan operation, connect the second signal path to a third voltage source to generate a second fail result signal and to output the second fail result signal to the base chip when the chip ID has a second combination.

2. The semiconductor device of claim 1, wherein during the scan operation, the base chip connects the first signal path to one of a first PMOS transistor and a first NMOS transistor and connects the second signal path to one of a second PMOS transistor and a second NMOS transistor.

3. The semiconductor device of claim 1, wherein the first memory chip connects the first signal path to one of a third PMOS transistor and a third NMOS transistor and generates the first fail result signal according to a logic level at the first signal path.

4. The semiconductor device of claim 1, wherein the second memory chip connects the second signal path to one of a fourth PMOS transistor and a fourth NMOS transistor and generates the second fail result signal according to a logic level at the second signal path.

5. The semiconductor device of claim 1, the first signal path and the second signal path are stacked through the base chip, the first chip, and the second chip that are stacked.

6. The semiconductor device of claim 1,
wherein the first signal path includes a first plurality of through vias and a first plurality of bumps and the second signal path includes a second plurality of through vias and a second plurality of bumps, and
wherein the first plurality of through vias and the first plurality of bumps included in the first signal path are electrically connected, and the second plurality of through vias and the second plurality of bumps included in the second signal path are electrically connected.

7. The semiconductor device of claim 1, wherein the base chip includes:
a test signal generation circuit configured to generate a scan enable signal that is enabled during the scan operation, generate a scan-down signal and a scan-up signal that are selectively enabled, and generate a down-latch signal and an up-latch signal that are selectively enabled;
a fail information signal generation circuit configured to serialize the first fail result signal and the second fail result signal to generate a first fail information signal and a second fail signal, respectively and to connect the first signal path and the second signal path based on the scan enable signal, the scan-down signal, the scan-up signal, the down-latch signal, and the up-latch signal to generate the first fail information signal and the second fail information signal; and
a fail detection circuit configured to detect connection fails of the first signal path and the second signal path based on logic levels of the first fail information signal and the second fail information signal.

8. The semiconductor device of claim 7, wherein the fail information signal generation circuit includes:
a first fail signal generation circuit configured to generate first base data from the first fail result signal when the scan enable signal is enabled and connect the first signal path to the first voltage source through one of the first PMOS transistor and the first NMOS transistor based on the scan-down signal and the scan-up signal to generate a first fail signal when the scan enable signal is enabled;
a second fail signal generation circuit configured to generate second base data from the second fail result signal when the scan enable signal is enabled and connect the second signal path to the first voltage source through one of the second PMOS transistor and the second NMOS transistor based on the scan-down signal and the scan-up signal to generate a second fail signal when the scan enable signal is enabled; and
a fail information signal output circuit configured to serialize the first base data and the second base data based on a test read signal in synchronization with a test clock signal to output the serialized first base data and second base data as the first fail information signal and the second fail information signal and to serialize the first fail signal and the second fail signal to output the serialized first fail signal and second fail signal as the first fail information signal and the second fail information signal when a base read signal is enabled.

9. The semiconductor device of claim 8, wherein the first fail signal generation circuit includes:
a first switching circuit configured to connect the first signal path to a first node to generate the first base data from the first fail result signal when the scan enable signal is enabled;
a first driving circuit configured to drive a voltage level of the first node by one of the first PMOS transistor and the first NMOS transistor based on the scan-down signal and the scan-up signal to generate the first base data;
a first storage circuit configured to store the first base data based on the down-latch signal and the up-latch signal and generate a first base comparison signal from the stored first base data; and
a first test mode control circuit configured to output the first base comparison signal as the first fail signal.

10. The semiconductor device of claim 8, wherein the second fail signal generation circuit includes:
a second switching circuit configured to connect the second signal path to a second node to generate the second base data from the second fail result signal when the scan enable signal is enabled;
a second driving circuit configured to drive a voltage level of the second node by one of the second PMOS transistor and the second NMOS transistor based on the scan-down signal and the scan-up signal to drive the second base data;
a second storage circuit configured to store the second base data based on the down-latch signal and the up-latch signal and generate a second base comparison signal from the stored second base data; and
a second test mode control circuit configured to output the second base comparison signal as the second fail signal.

11. The semiconductor device of claim 8, wherein the fail information signal output circuit includes:
a first fail information signal output circuit configured to generate the first fail information signal based on the first base data when the base read signal is disabled in synchronization with the test clock signal and to generate the first fail information signal based on the first fail signal when the base read signal is enabled; and
a second fail information signal output circuit configured to generate the second fail information signal based on the second base data to output the second fail information signal to an output pad when the base read signal is disabled and the test read signal is disabled in synchronization with the test clock signal, to generate the second fail information signal based on the first fail information signal to output the second fail information signal to the output pad when the base read signal is disabled and the test read signal is enabled in synchronization with the test clock signal, and to generate the second fail information signal based on the second fail signal to output the second fail information signal to the output pad when the base read signal is enabled in synchronization with the test clock signal.

12. The semiconductor device of claim 1, wherein the first memory chip further includes a first fail result signal generation circuit connected to the first signal path and is configured to connect the first signal path to the second voltage source based on the scan-down signal and the scan-up signal to generate the first fail result signal when the chip ID has the first combination and output the first fail result signal to the first signal path.

13. The semiconductor device of claim 12, wherein the first fail result signal generation circuit includes:
a first memory control circuit configured to generate a first switching signal and a first memory read signal that are enabled when a core read signal is enabled and the chip ID has the first combination;
a third switching circuit configured to connect the first signal path to a third node and output first memory data as the first fail result signal when the first switching signal is enabled;
a third driving circuit configured to drive a voltage level of the third node by one of the third PMOS transistor and the third NMOS transistor based on the scan-down signal and the scan-up signal to generate the first memory data when the first memory read data is disabled and to drive a voltage level of the third node by one of the third PMOS transistor and the third NMOS transistor based on a first pass signal to generate the first memory data when the first memory read signal is enabled;
a third storage circuit configured to store the first memory data based on the down-latch signal and the up-latch signal and to generate a first memory comparison signal from the stored first memory data; and
a first core test mode control circuit configured to output the first memory comparison signal as the first pass signal.

14. The semiconductor device of claim 1, wherein the second memory chip further includes a second fail result signal generation circuit connected to the second signal path and is configured to connect the second signal path to the third voltage source based on the scan-down signal and the scan-up signal to generate the second fail result signal when the chip ID has the second combination and output the second fail result signal to the second signal path.

15. The semiconductor device of claim 14, wherein the second fail result signal generation circuit includes:
a second memory control circuit configured to generate a second switching signal and a second memory read signal that are enabled when a core read signal is enabled and the chip ID has the second combination;
a fourth switching circuit configured to connect the second signal path to a fourth node and output second memory data as the second fail result signal when the second switching signal is enabled;
a fourth driving circuit configured to drive a voltage level of the fourth node by one of the fourth PMOS transistor and the fourth NMOS transistor based on the scan-down signal and the scan-up signal to generate the second memory data when the second memory read data is disabled and to drive a voltage level of the fourth node by one of the fourth PMOS transistor and the fourth NMOS transistor based on a second pass signal to generate the second memory data when the second memory read data is enabled;
a fourth storage circuit configured to store the second memory data, based on the down-latch signal and the up-latch signal, and generate a second memory comparison signal from the stored second memory data; and
a second core test mode control circuit configured to output the second memory comparison signal as the second pass signal.

16. A semiconductor device comprising:
a base chip configured to generate a fail information signal at a second logic level after generating the fail information signal at a first logic level during a test mode, to drive a signal path to a first voltage level during a scan operation, and to generate the fail information signal based on a fail result signal to detect a connection fail of the signal path; and
a memory chip configured to generate the fail result signal at the second logic level after generating the fail result signal at the first logic level during the test mode, to drive the signal path to a second voltage level to generate the fail result signal during the scan operation, and output the fail result signal to the base chip according to a chip identification (ID).

17. The semiconductor device of claim 16, wherein the base chip drives the signal path to the first voltage level by one of a first PMOS transistor and a first NMOS transistor during the scan operation.

18. The semiconductor device of claim 16, wherein the memory chip drives the signal path to the second voltage level by one of a second PMOS transistor and a second NMOS transistor during the scan operation.

19. The semiconductor device of claim 16, wherein the base chip detects no fail in the signal path when the fail information signal is generated at the first logic level after the scan operation.

20. The semiconductor device of claim 16, wherein the base chip detects a resistance fail in the signal path when the fail information signal is generated at the second logic level after the scan operation.

21. The semiconductor device of claim 16, wherein the base chip detects an open fail including a disconnect in the signal path when the fail information signal is generated at one of the first logic level and the second logic level during the test mode and the fail information is generated at a same logic level as the fail information signal during the test mode during the scan operation.

22. The semiconductor device of claim 16, wherein the base chip includes:
a test signal generation circuit configured to generate a scan enable signal that is enabled during the scan operation, generate a scan-down signal and a scan-up signal that are selectively enabled, and generate a down-latch signal and an up-latch signal that are selectively enabled;
a fail information signal generation circuit configured to generate a fail signal at the second logic level after generating the fail signal at the first logic level in the test mode, connect the signal path based on the scan enable signal, the scan-down signal, the scan-up signal, the down-latch signal, and the up-latch signal to generate the fail signal and generate the fail information signal based on the fail result signal; and
a fail detection circuit configured to detect a connection fail of the signal path based on a logic level of the fail information signal.

23. The semiconductor device of claim 22, wherein the fail information signal generation circuit includes:
a fail signal generation circuit configured to generate the fail signal at the second logic level after generating the fail signal at the first logic level during the test mode, to receive the fail result signal when the scan enable signal is enabled, and to drive the signal path to a first voltage level by one of a first PMOS transistor and a first NMOS transistor based on the scan-down signal and the scan-up signal to generate the fail signal when the scan enable signal is enabled; and
a fail information signal output circuit configured to generate the fail information signal based on base data generated according to a logic level of the signal path in synchronization with a test clock signal and output the fail signal as the fail information signal when a base read signal is enabled.

24. The semiconductor device of claim 23, wherein the fail signal generation circuit includes:
a first switching circuit configured to connect the signal path to a first node when the scan enable signal is enabled;
a first driving circuit configured to drive the first node to the first voltage level by one of the first PMOS transistor and the first NMOS transistor based on the scan-down signal and the scan-up signal to generate the base data;
a first storage circuit configured to store the base data based on the down-latch signal and the up-latch signal and to generate a base comparison signal from the stored base data; and
a test mode control circuit configured to, during the test mode, generate the fail signal at the first logic level when a test disable signal is enabled, to generate the fail signal at the second logic level when a test reset signal is enabled, and to output the first base comparison signal as the fail signal during the scan operation.

25. The semiconductor device of claim 16, wherein the memory chip includes a fail result signal generation circuit configured to, during the test mode, generate the fail result signal at the second logic level after generating the fail result signal at the first logic level, to connect the signal path based on the scan-down signal and the scan-up signal to generate the fail result signal when the chip ID has a combination in the scan operation, and to output the fail result signal to the signal path.

26. The semiconductor device of claim 25, wherein the fail result signal generation circuit includes:
a memory control circuit configured to generate a switching signal and a memory read signal that are enabled when a core read signal is enabled and the chip ID has the combination;
a second switching circuit configured to connect the signal path to a second node and to output memory data as the fail result signal when the switching signal is enabled;
a second driving circuit configured to drive the second node to the second voltage level by one of the second PMOS transistor and the second NMOS transistor based on the scan-down signal and the scan-up signal to generate the memory data when the memory read signal is disabled and to drive the second node to the second voltage level by one of the second PMOS transistor and the second NMOS transistor based on a pass signal to generate the memory data when the memory read signal is enabled;
a second storage circuit configured to store the memory data based on the down-latch signal and the up-latch signal and to generate a memory comparison signal from the stored memory data; and
a core test mode control circuit configured to, during the test mode, generate the pass signal at the second logic level when a test disable signal is enabled, to generate the pass signal at the first logic level when a test reset signal is enabled, and to output the memory comparison signal as the pass signal during the scan operation.

27. A semiconductor device comprising:
a base chip configured to drive a signal path to a first voltage level during a scan operation and to detect a connection fail of the signal path from a fail information signal generated based on a fail result signal; and
a memory chip configured to drive the signal path to a second voltage level during the scan operation to generate the fail result signal and output the fail result signal to the base chip according to a chip identification, wherein the signal path extends through the base chip and the memory chip.
